(19) United States
(12) Patent Application Publication
(10) Pub. No.: US 2012/0070685 A1
(43) Pub. Date: Mar. 22, 2012

(54) COMPOSITIONS COMPRISING POLYMERS COATED WITH METALLIC LAYERS AND METHODS OF MANUFACTURE AND USE THEREOF

(76) Inventors: Terence KLOSS, Mechanicsville, PA (US); Cynthia Kuper, Villanova, PA (US)

(21) Appl. No.: 13/159,187

(22) Filed: Jun. 13, 2011

Related U.S. Application Data
(60) Provisional application No. 61/353,932, filed on Jun. 11, 2010.

(51) Int. Cl. B32B 15/095; C23C 16/06; B32B 5/18; B32B 5/02; B32B 27/40; B32B 15/20

(52) U.S. Cl. 428/626; 428/425.8; 428/319.1; 442/164; 428/333; 427/250

(57) ABSTRACT

The invention generally encompasses compositions comprising polymers coated with one or more metallic layers. In certain embodiments, the invention encompasses compositions comprising polyurethane foam coated with one or more metallic layers. The invention also encompasses methods of coating polymers using vapor depositions techniques, for example, physical vapor deposition, with one or more metallic layers. The invention further encompasses articles of manufacture including the compositions of the invention.

### FIELD OF THE INVENTION

The invention generally encompasses compositions comprising polymers coated with one or more metallic layers. In certain embodiments, the invention encompasses compositions comprising polyurethane foam or polyurethane fabric coated with one or more metallic layers. The invention also encompasses methods of coating polymers using vapor depositions techniques, for example, physical vapor deposition, with one or more metallic layers. The invention further encompasses articles of manufacture including the compositions of the invention.

### BACKGROUND OF THE INVENTION

Physical vapor deposition (PVD) is a type of vacuum deposition and is a general term used to describe any of a variety of methods to deposit thin substrates by the condensation of a vaporized form of the material onto various surfaces (e.g., onto semiconductor wafers). The coating method involves physical processes such as high temperature vacuum evaporation or plasma sputter bombardment rather than involving a chemical reaction at the surface to be coated as in chemical vapor deposition.

Variants of PVD include, for example, (i) evaporative deposition: in which the material to be deposited is heated to a high vapor pressure by electrically resistive heating in “low” vacuum; (ii) electron beam physical vapor deposition: in which the material to be deposited is heated to a high vapor pressure by electron bombardment in “high” vacuum; (iii) sputter deposition: in which a glow plasma discharge (usually localized around the “target” by a magnet) bombards the material sputtering some away as a vapor; (iv) cathodic arc deposition: in which a high power arc directed at the target material blasts away some into a vapor; and (v) pulsed laser deposition: in which a high power laser ablates material from the target into a vapor.

PVD is used in the manufacture of items including semiconductor devices, aluminized PET substrate for balloons and snack bags, and coated cutting tools for metalworking. Other examples include nickel/chromium and/or chromium electroplating on aluminum and steel parts to provide a rich, reflective, chrome finish widely accepted, desired, and used in the automotive, furnishing and like industries. Chrome plating requires the use of hazardous solutions and bi-products that present numerous environmental issues and problems. In addition, since chromium is a very hard material, it is well known that a layer of material having high chromium content that is plated on a substrate tends to fracture or “craze” when the substrate is flexed and/or thermally expanded.

The inventors have surprisingly found that certain stretchable polymer materials and fabric materials can be coated with metals using physical vapor deposition. The resulting materials have unique and brilliant metallic appearance that can be stretched to the full extent of the substrate material with no visible signs of damage to the metal layer and without discernable de-lamination or flaking of the metal layer when the material is stretched to its extent over a glossy white surface to measure debris.

### SUMMARY OF THE INVENTION

In one embodiment, the invention encompasses a composition comprising polyurethane coated with one or more metals to form one or more thin-substrate metal layers.

In another embodiment, the invention encompasses a method of providing one or more metal layers to a polyurethane substrate comprising:

a. applying a thin substrate of a metal by physical vapor deposition onto the surface of the polyurethane substrate.

In another embodiment, the invention encompasses methods for enhancing the appearance of polyurethane foam through the use of vacuum metallization, for example, physical vapor deposition (PVD) techniques including, but not limited to, evaporation and sputtering.

The inventors have surprisingly found that the open cell structure of polyurethane, particularly, polyurethane foam, makes the material unexpectedly compatible with vacuum processing. This is surprising since foam materials generally trap gasses, which interfere with the vacuum pumps ability to remove gas from the chamber by slowly releasing the trapped gas from the material. These trapped gasses are a further detriment by continuing to be released during deposition which contaminates and discolors the metal film.

It has further been discovered that the structure of the foam provides for a unique and brilliant metal finish. Its surface contains inherent sparkle in raw form interspersed with holes, which are enhanced and highlighted by the metal coating.

In another embodiment, the invention encompasses a composition comprising a gemstone with one or more metals to form one or more thin-substrate metal layers. Gemstones include diamonds, rubies, pearls, emeralds and other gemstones known in the jewelry industry. The gemstones include crushed, rough and faceted, white, colored gemstones.

In another embodiment, the invention encompasses utilizing PVD processes on polyurethane foam substrates, which produce a unique aesthetic exemplified by the 3 dimensional cellular structure of the material and the residual membranes spanning the cells termed “windows,” which produce a mirrored reflection adding sparkle to the coated substrate.

The inventors envision multiple and diverse applications for such materials including, but not limited to, in the automotive industry, the textile industry, silicon wafer manufacturing, military use, and the athletic industry.

### BRIEF DESCRIPTION OF THE FIGURES

A more complete understanding of the present invention may be obtained by reference to the accompanying drawings, when considered in conjunction with the subsequent detailed description. The embodiments illustrated in the drawings are intended only to exemplify the invention and should not be construed as limiting the invention to the illustrated embodiments, in which:

FIG. 1 illustrates a non-limiting, exemplary polyurethane foam substrate coated with aluminum and a titanium coating using physical vapor deposition.

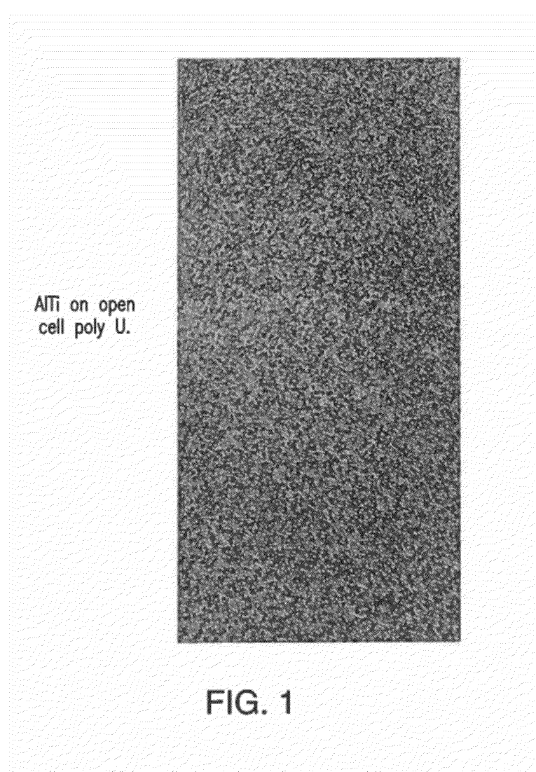

FIG. 2 illustrates a non-limiting, exemplary polyurethane foam substrate coated with a copper coating using physical vapor deposition.

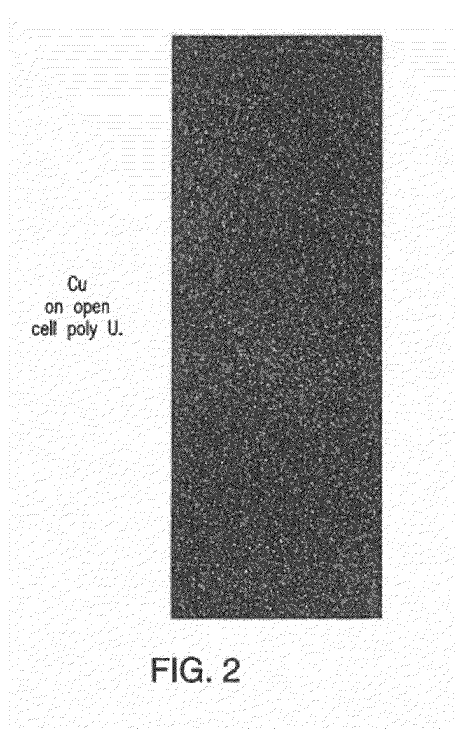

FIG. 3 illustrates a non-limiting, exemplary polyurethane foam substrate coated with a copper and a silver coating using physical vapor deposition.

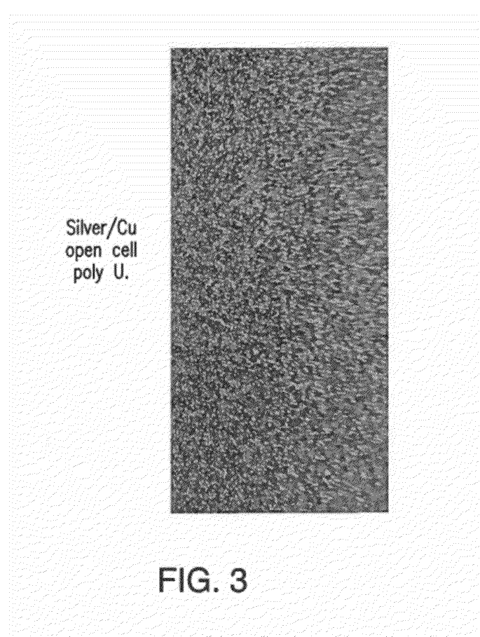

FIG. 4 illustrates a non-limiting, exemplary polyurethane foam substrate coated with a silver coating using physical vapor deposition.

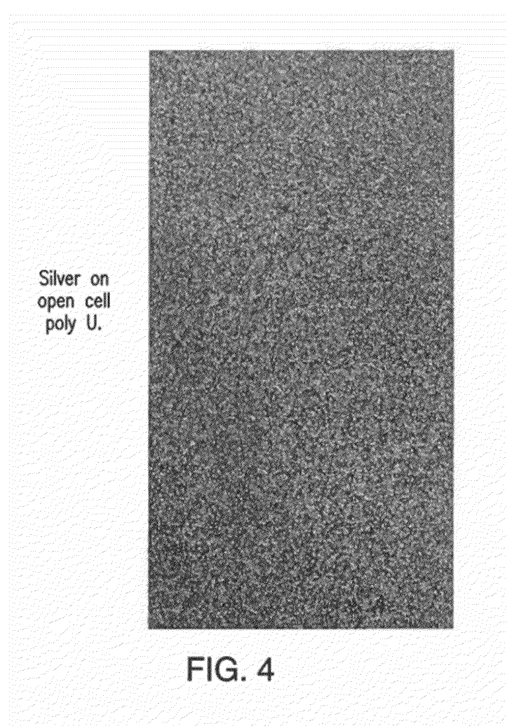

FIG. 5 illustrates a non-limiting, exemplary polyurethane foam substrate coated with a copper and a zinc (i.e., brass) coating using physical vapor deposition.

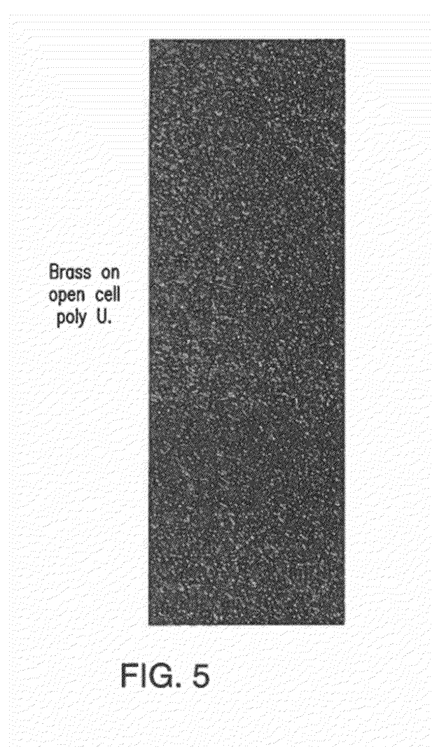

FIG. 6 illustrates a non-limiting, exemplary polyurethane foam substrates coated with the following metals from left to right—Al/Ti, Cu, Cu/Ag, Al/Cr, Al, Ag, Cu/Zn (i.e., Yellow Brass), and Pd using physical vapor deposition.

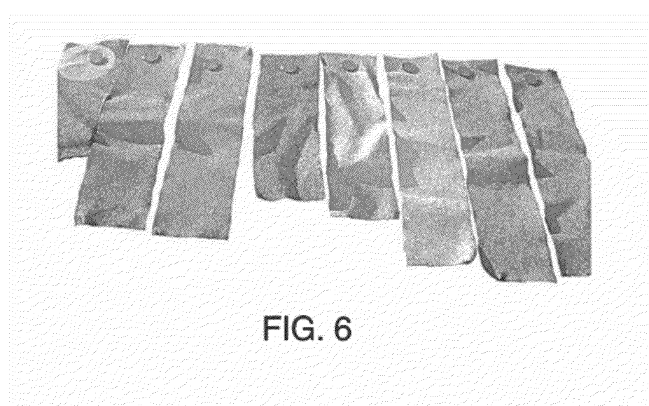

### DETAILED DESCRIPTION OF THE INVENTION

The invention generally encompasses a composition comprising polyurethane coated with one or more metals to form one or more thin-substrate metal layers.

In certain exemplary embodiments, the polyurethane is polyurethane foam.

In certain exemplary embodiments, the polyurethane is polyurethane fabric.

In certain exemplary embodiments, the metal comprises aluminum, copper, silver, gold, chromium, titanium, palladium, zinc, and platinum or a mixture thereof.

In certain exemplary embodiments, the polyurethane foam is in an open cell structure.

In certain exemplary embodiments, the polyurethane fabric is Lyera® or Spandex®.

In certain exemplary embodiments, the one or more thin-substrate metal layers comprise uniform layers coating the polyurethane.

In certain exemplary embodiments, the one or more thin-substrate metal layers comprise a thickness of about 20 Angstroms to 2000 Angstroms.

In certain exemplary embodiments, the one or more thin-substrate metal layers comprise a thickness of about 50 Angstroms to 1500 Angstroms.

In certain exemplary embodiments, the one or more thin-substrate metal layers comprise a thickness of about 100 Angstroms to 1000 Angstroms.

In certain exemplary embodiments, the one or more thin-substrate metal layers comprise a thickness of about 150 Angstroms to 500 Angstroms.

In certain exemplary embodiments, the thin-substrate metal layers comprise more than one layer.

In certain exemplary embodiments, the polyurethane is coated with copper and silver.

In certain exemplary embodiments, the copper and silver vary in amount from about 1% to about 99%.

In certain exemplary embodiments, the copper and silver vary in amount from about 1% to about 99% and have a total thickness of about 500 Angstroms.

In another embodiment, the invention encompasses a method of providing one or more metal layers to a polyurethane substrate comprising:

a. applying a thin substrate of a metal by physical vapor deposition onto the surface of the polyurethane substrate.

In certain exemplary embodiments of the methods of the invention, the polyurethane substrate is polyurethane foam.

In certain exemplary embodiments of the methods of the invention, the polyurethane substrate is polyurethane fabric.

In certain exemplary embodiments of the methods of the invention, the metal comprises aluminum, copper, silver, gold, chromium, titanium, palladium, zinc, and platinum or a mixture thereof.

In certain exemplary embodiments of the methods of the invention, the polyurethane foam is in an open cell structure.

/In certain exemplary embodiments of the methods of the invention, the polyurethane fabric is Lycra® or Spandex®.

In certain exemplary embodiments of the methods of the invention, the one or more thin-substrate metal layers comprise uniform layers coating the polyurethane.

In certain exemplary embodiments of the methods of the invention, the one or more thin-substrate metal layers comprise a thickness of about 20 Angstroms to 2000 Angstroms.

In certain exemplary embodiments of the methods of the invention, the one or more thin-substrate metal layers comprise a thickness of about 100 Angstroms to 1500 Angstroms.

In certain exemplary embodiments of the methods of the invention, the one or more thin-substrate metal layers comprise a thickness of about 200 Angstroms to 1000 Angstroms.

In certain exemplary embodiments of the methods of the invention further comprise applying one or more additional thin substrates of a metal by physical vapor deposition onto the surface of the polyurethane substrate.

In certain exemplary embodiments of the methods of the invention, the polyurethane is coated with copper and silver.

In certain exemplary embodiments of the methods of the invention, the copper and silver vary in amount from about 1% to about 99%.

In certain exemplary embodiments of the methods of the invention, the copper and silver vary in amount from about 1% to about 99% and have a total thickness of about 500 Angstroms.

### The Compositions of the Invention

The compositions of the invention include polymer substrates coated with a metallic substrate or coating using, for example, physical vapor deposition.

In certain embodiments, the invention encompasses compositions comprising a polymer substrate, for example, polyurethane including but not limited to polyurethane foam and polyurethane fabric (e.g., Lycra® or Spandex®) and a metallic coating on the polymer. The coating is formed by depositing a continuous layer of metallic substance by a physical vapor deposition method. The majority of the metal particles are usually elemental metal particles, although other metallic particles such as, for example, metal oxides, metal nitrides and alloys are also contemplated.

In certain embodiments, the invention encompasses compositions comprising a polymer substrate, for example polyethylene (e.g., synthetic Tulle or Organza) and a metallic coating on the polymer. The coating is formed by depositing a continuous layer of metallic substance by a physical vapor deposition method. The majority of the metal particles are elemental metal particles, although other metallic particles such as, for example, metal oxides, metal nitrides and alloys are also contemplated.

In certain embodiments, the invention encompasses compositions comprising a polymer, for example polyurethane foam; and a ceramic coating on the polymer. The coating is formed by depositing a continuous layer of a ceramic substance by a physical vapor deposition.

In certain embodiments, the invention encompasses compositions comprising a gemstone, for example diamonds, rubies, pearls, emeralds; and a ceramic coating. The coating is formed by depositing a continuous layer of a ceramic substance by a physical vapor deposition.

In other embodiments, the invention encompasses compositions comprising a gemstone, for example, diamonds, rubies, pearls, emeralds; and a metallic coating on the gemstone. The coating is formed by depositing a continuous layer of metallic substance by a physical vapor deposition method. The majority of the metal particles are usually elemental metal particles, although other metallic particles such as, for example, metal oxides, metal nitrides and alloys are also contemplated.

In other embodiments, the invention encompasses compositions comprising a polymer tubing or solid polymer cording, for example, polyurethane, polystyrene, nylon, polycarbonate; and a metallic coating on the tubing such that a continuous metal layer is formed which is flexible and does not chafe, flake or crack when the flexible tubing or cording is bent, stretched or cut or if the rigid cording or tubing is cut. The coating is formed by depositing a continuous layer of metallic substance by a physical vapor deposition method. The majority of the metal particles are usually elemental metal particles, although other metallic particles such as, for example, metal oxides, metal nitrides and alloys are also contemplated. In certain embodiments the polyurethane cording is coated with a continuous metal layer as a fashion accessory, necklace, bracelet or ring.

In other embodiments metallic coated gemstones are placed inside or suspended, in polymer matrices such as polyalcrylates, cyanoacrylates etc. In certain embodiments, small rough, or uncut, diamonds are coated with a continuous metal nitride (e.g., with TiN) coating and suspended in a cyanoacrylate such that that metal coated gem stones maybe protected and viewed from this setting as a novelty, fashion accessory, necklace, bracelet or ring.

In other embodiments, the invention encompasses compositions comprising a polystyrene foam, for example, Styrofoam®. The coating is formed by depositing a continuous layer of metallic substance by a physical vapor deposition method. The majority of the metal particles are usually elemental metal particles, although other metallic particles such as, for example, metal oxides, metal nitrides and alloys are also contemplated. In certain embodiments, the polyurethane foam is used as substrate for metallization and ceramic coating (e.g., with TiN) for a fashion accessory and display accessory, like that in a display case or window in varying shapes, and as jewelry in varying shapes such as spheres, or hoops.

As used herein, “continuous” means the metal coating is disposed as a uniform coating of particles, with little to no uncoated areas, such that the coating exhibits surface coating uniformity. Although, if desired the coating can be applied to the polymer substrate in a less than continuous manner or can be coated to create varying patterns.

The invention also encompasses methods of forming a metal coating on a polymer substrate, for example, polyurethane including but not limited to polyurethane foam and polyurethane fabric (e.g., Lycra® or Spandex®). The methods include coating a polymer substrate, for example, polyurethane including but not limited to polyurethane foam and polyurethane fabric (e.g., Lycra® or Spandex® with a coating of metallic particles by physical vapor deposition.

The invention encompasses a metallic coating on a polymer substrate, for example, polyurethane including but not limited to polyurethane foam and polyurethane fabric (e.g., Lycra® or Spandex®). The coating generally has an average thickness of less than 5000 Angstrom, in certain embodiments less than 4000 Angstrom, in certain embodiments less than 3000 Angstrom, in certain embodiments less than 2000 Angstrom, in certain embodiments less than 1000 Angstrom, in certain embodiments less than 800 Angstrom, in certain embodiments less than 600 Angstrom, in certain embodiments less than 500 Angstrom, in certain embodiments less than 400 Angstrom, in certain embodiments less than 200 Angstrom, in certain embodiments less than 100 Angstrom, in certain embodiments less than 50 Angstrom.

The size and shape of the metallic particles coating the polymer can vary; however, in certain embodiments, metal coating particles can be substantially spherical, but in some cases are elongated, having an aspect ratio (length to diameter) of greater than 1.5:1 (i.e. are substantially oblong).

Average thickness of the metal coating may be measured during deposition using a commercially available quartz crystal microbalance. After deposition a number of chemical assays can be used to characterize the quantity of metal in any specified area. Particle diameter (formed by agglomeration of the particles) is typically measured using light scattering techniques known in the art. Primary particle diameter is typically measured using transmission electron microscopy or atomic force microscopy.

Metals that may coat the compositions of the invention will vary depending on the application and can include, for example, Li, Na, K, Rb, Cs, Fr, Be, Mg, Ca, Sr, Ba, Ra, Y, La, Ac, Ti, Zr, Hf, V, Nb, Ta, Cr, Mo, W, Mn, Tc, Re, Fe, Ru, Os, Co, Rh, Tr, Ni, Pd, Pt, Cu, Ag, Au, Zn, Cd, Al, In, TI, Sn, Pb, mixtures thereof, oxides and alloys of these metals and even the lanthanides and actinides, if desired. Metals may be deposited sequentially or simultaneously.

In certain particular embodiments, metals include, but are not limited to, gold, aluminum, copper, iron, platinum, palladium, iridium, rhodium, osmium, ruthenium, titanium, titanium nitride, cobalt, vanadium, magnesium, silver, zinc, and cadmium, indium, lanthanum, indium tin oxide (ITO) and antimony tin oxide (ATO), antimony indium tin oxide (AlTO), titanium nitride, aluminum nitride, silver nitride, gold nitride, tin, indium, lanthanum, boron, lanthanum hexaboride, rare earth metals and mixtures and alloys thereof, and mixtures and alloys thereof.

In certain particular embodiments, ceramics include, inorganic nonmetallic materials, generally including oxides, nitrides, borides, carbides, silicides, and sulfides as well as intermetallic compounds such as aluminides and beryllides and phosphides, antimonides, and arsenides.

In other embodiments, the metals that can be used to coat the polymer substrates include aluminum, copper, silver, gold, chromium, titanium, palladium, zinc, and platinum or a mixture or alloy thereof.

Examples of polymers that can be used in the compositions of the invention include, but are not limited to, polyesters, polyurethanes, polyamides, polystyrene, polyiraides, polyolefins, alkyd, fluoropolymers, liquid crystal polymers, melamine, urea formaldehyde, diallyl phthalate, epoxide, phenolic, polyvinyl chloride, ionomeric polymers, acrylics and silicone polymers. Processes for preparing the polymers are well known, and the invention is not limited to a polymer made with a particular catalyst or process. The polymer substrate may be a single or multi-layer polymer substrate.

A preferred polymer of the invention includes polyurethane including, but not limited to, polyurethane foam and polyurethane fabric (e.g., Lycra® or Spandex®).

In certain embodiments of the invention, polymers include poly(alpha)olefins. Poly(alpha)olefins can include the homo-, co- and terpolymers of aliphatic mono-alpha-olefins as they are generally recognized in the art. Usually, the monomers employed in making such poly(alpha)olefins contain about 2 to 10 carbon atoms per molecule, though higher molecular weight monomers sometimes are used as comonomers. The invention is applicable also to blends of the polymers and copolymers prepared mechanically or in situ. Examples of useful monomers that can be employed to prepare the thermoplastic polymers include ethylene, propylene, 1-butene, 1-pentene, 4-methyl-1-pentene, 1 hexene, and 1-octene, alone, or in admixture, or in sequential polymerization systems. Examples of preferred thermoplastic polymers include polyethylene, polypropylene, propylene/ethylene copolymers, polybutylene and blends thereof.

In other embodiments any polymer may be preferred. Useful polymers include polymers having terephthalate or naplithalate comonorner units, for example, polyethylene naphthalate (PEN), polyethylene terephthalate (PET) and copolymers and blends thereof. Examples of other suitable polyester copolymers are provided in, for example, U.S. Pat. Nos. 6,827,886 (Liu et al.), 6,808,658 (Stover et al), 6,830,713 (Hebrink et al) and 6,783,349 (Liu et al), which are incorporated herein by reference. Other suitable polyester materials include polycarbonates, polyarylates, and other naphthalate and terephthalate-containing polymers, such as, for example, polybutylene naphthalate (PBN), polypropylene naphtahalate (PPN), and blends and copolymers of the above with each other or with non-polyester polymers.

In certain embodiments, the polymer optionally can include particulate additives such as pigments, fillers, and reinfbrcing agents. Generally, such additives, if present, are less than 1 wt, % of the thermoplastic polymer substrate.

The polymer substrate may be stretched before or after deposition of the metallic particles. It will be understood however that whether the substrate is stretched or unstretched prior to particle deposition, the coated substrate may be subsequently stretched (or shrunk) without major loss of metallic coating. As used herein, the term “without major loss” means that greater than after stretching the polymer greater than about 50% of the metal coating remains on the polymer substrate, in certain embodiments greater than 60% of the metal coating remains on the polymer substrate, in certain embodiments greater than 70% of the metal coating remains on the polymer substrate, in certain embodiments greater than 80% of the metal coating remains on the polymer substrate, in certain embodiments greater than 90% of the metal coating remains on the polymer substrate, in certain embodiments greater than 95% of the metal coating remains on the polymer substrate, in certain embodiments greater than 99% of the metal coating remains on the polymer substrate, and in certain embodiments about 100% of the metal coating remains on the polymer substrate.

Generally the stretch does not impart a permanent deformation to the polymer substrate so that the dimensions (length and/or width) when increased return to the approximate starting dimensions.

The polymer substrate may be stretched along one major axis (uniaxial) and may further be stretched along two major axes (biaxial). The stretching may be sequential or simultaneous. The degree of stretching is generally defined by the draw ratio, that is, the ratio of the final area to the original area.

The present invention provides a polymeric substrate, having a continuous metallic particle coating onto at least a portion in certain embodiments covering the entirety of the polymeric substrate.

Although not necessary, if desired, the article may comprise a protective layer for isolating the particles from environmental effects and mechanical stresses. The additional layer may be in contact with the metallic particle layer on the surface of the polymer substrate layer. This layer can act to reduce the surface roughness of both the polymeric layer and the overall construction, maintain the clarity and low haze of the article, and protect the particle layer from abrasion or oxidation. The protective layer may also be used to impart scratch resistance, chemical resistance and/or increased weatherability. The protective layer can be co-extruded onto the surfaces of the coated surface of the polymer substrate layer. Alternatively, the protective layer can be coated or laminated onto the polymer substrate layer using a suitable pressure sensitive or non-pressure sensitive adhesive. Suitable coatings include, but are not limited to, hardcoats, adhesives, antistatics, adhesion promoting primers, LTV stabilizing coating, friction reduction layers, etc. The protective layers are preferably made of a transparent polymer, for example, polyester (the same or different as that used in the construction of the thermoplastic polymer substrate layer.

Although not necessary, if desired, the article may comprise an additional layer or backing, on the underside of the metal coated polymer foam for supporting, protecting, adding functionality or increasing breadth of application to the metal coated polymer foam. The under layer may be laminated or otherwise adhered to the metal coated polymer layer, for example by thermal or flame lamination. In the case of thermal lamination a heat activated or pressure sensitive adhesive may be used as an intermediate layer to seal the underside of the metal coated polymer to the under layer. This under layer, or backing layer can act to reduce or enhance the surface roughness of the underside of the metal coated polymeric layer and the overall construction, for applications such a stitchability, for applying the metal coated polymer to uses in fashion and apparel, such as in the construction of a garment or fashion accessory like a hand bag, shoe, scarf or belt. The backing layer may also be used to protect the metal coated polymer layer from ripping, tearing and other mechanically induced stress failure mechanisms. The backing layer may also be used to impart chemical resistance and/or increased weatherability and wearability. Suitable materials for this backing layer include, but are not limited to, adhesives, antistatics, adhesion promoting primers, UV stabilizing materials, friction reduction layers, etc. The backing layers may also include other polyethylene, polyurethane and nylon fabrics, polymer foams as well as, metals, polyvinyls and natural hides such as leather. Furthermore the backing layer may be another polymer foam having application as a cosmetic applicator, such as a cosmetic sponge or a construction of materials such as a puff, comprising a sewn sack in which other material are placed inside, for use as a cosmetic applicator.

Although not necessary, if desired, the article may comprise the addition of a top protective layer in contact with the metal particles of the metal coated polymer and an under layer, or backing layer, on the underside of the metal coated polymer.

The resulting metal coated polymer article may be characterized as a stretchable or shrinkable substrate having a continuous coating of metal particles on the surface of the polymer.

If desired, a multilayer metal coated polymer article comprised of a plurality of metal coatings may be used. The substrates may be bonded or otherwise affixed to adjacent layers, or may comprise a stack of particle coated substrates. The multilayer article further shows an internal reflectance between layers.

The particles are partially fixed on the surface of the polymer substrate and exposed, rather than embedded therein, Electron micrographs of a cross section of the coated article indicate the particles are substantially above the plane of the substrate. Generally more than 50%, typically more than 75% of the volume of the particles is above the surface. The particles remain fixed on the surface and are not easily removed. Typically less than 5% of the particles are removed by a tape test in which adhesive tape is affixed to the surface, and then peeled off at 180 degrees.

The metal coated polymer articles of the invention can be used, for example, as an article of clothing, a bandage, a decorative design, in the automotive industry for coating automobile parts, as a support, for example, as athletic tape, or as an adhesive tape.

Accordingly, the metal coated polymer article when used as a bandage or for medical purposes can further include a coating such as but not limited to, antibacterial agents, antibiotics, anti-infective agents, and therapeutic agents.

The metal coated article can further be used as a component in the construction of a cosmetic applicator, such as the tip of an eye shadow applicator or used alone as an applicator for foundation, powder or other suitable cosmetic product, to impart a unique aesthetic to the applicator itself or for the purposes of creating a surface roughness on the applicator to impart a unique aesthetic of the cosmetic onto the skin.

In another embodiment, the metal coated polymer foam can be used as a cosmetic applicator to impart a unique aesthetic of the cosmetic onto the skin. Such an embodiment in the present invention is particularly useful in applying liquid crystalline cosmetics to the skin whereby a highly reticulated metal coated polymer foam creates a highly roughened surface that serves to mechanically deform, or sheer stress, the liquid crystal cosmetic as it is being applied to the skin, using such article. The resulting liquid crystal cosmetic may appear uniquely light reflecting and/or refracting on the skin creating desirable patterns and colors and impart control over those patterns.

In another embodiment, the metal coated polymer foam may be used as an applicator for nail lacquer. In such an embodiment the metal coated polymer foam may serve to impart unique patterns in the lacquer on the nail. Such an example would be using a highly reticulated polymer foam to mechanically manipulate the color particles in the lacquer yielding unique aesthetic of such lacquer on the nail. In such an embodiment the reticulated polymer foam may or may not be coated with metal.

In another embodiment, the metal coated polymer article can be used as a sensor. The sensor(s) of the invention are preferably employed in combination with a means for detection of transmitted light in the ultraviolet region (about 200 to about 400 nm), visible region (about 400 to about 750 nm) and/or infrared region (greater than about 750 nm) of the spectrum. Such an embodiment of the present invention is particularly useful for use in an endpoint-assay or as a screening tool in combinatorial chemistry, proteomics and/or genomics.

In another embodiment the metal coated polymer foam, with or without the addition of a top protective top layer and/or backing layer may, be used as a decorative layer for the top of a cosmetic applicator such as a puff or sponge.

Additionally, the use of the metal coated polymer foam, with or without the addition of a protective top layer and/or backing layer, may also be used as a decorative component or construction of packaging including but not limited to the packaging of cosmetics such as a pouch that holds a cosmetic compact, or lipstick.

In another embodiment of the invention the metal coated polymer may be used as a fashion accessory in a particularly unique application of body art, where by the metal coated polymer foam, with or without a top protective layer, with the addition of an adhesive backing layer is applied directly on the skin. Such an example would be a metal coated polymer with a pressure sensitive adhesive that would allow for the protective layer of the adhesive to be peeled off and the pressure sensitive adhesive backed metal coated polymer article to be stuck directly onto the body.

In an additional embodiment the metal coated polymer foam, with or without the addition of a top protective layer, may have a pressure sensitive, or heat activated, adhesive backing layer which enables the article to be heat sealed onto another article for decorative purposes, such as an “iron-on” fashion accessory.

### Methods of Manufacturing the Compositions of the Invention

The metallic coating particles are prepared by physical vapor deposition techniques that generate the particles. Metal is heated under reduced pressure until vaporization occurs. Optionally, the metal vaporizes in the presence of a gas stream wherein the gas preferably is inert (nonreactive), although any gas that does not react with the metal may be used. The particles are transported or directed to a polymeric substrate (optionally by the gas stream) and deposited by impinging the metallic vapor onto the polymer substrate, wherein nucleation and particle growth occurs. Generally in the absence of a gas stream the physical vapor deposition technique produces a metallic vapor than directly nucleates on the polymer substrate surface. In the presence of a gas, the metallic vapor undergoes some degree of homogenous nucleation in the stream to produce the particles, which are deposited uniformly on the polymer substrate surface.

The coating may be prepared by a method comprising the steps: a) vaporizing a metal, optionally in the presence of a nonreactive gas stream, to provide metallic vapor, b) optionally providing a second reactive gas capable of reacting with the metallic vapor (or metallic particles formed in the metallic vapor), and reacting the reactive gas with the metallic vapor (or metallic particles) to convert the same to metal particles, and c) impinging the metallic vapor onto the polymer surface, wherein nucleation and growth of the metal coating particles occurs, to provide a particle coating on the polymer.

The deposition of the metallic particles on the polymeric substrate may be achieved using one of several physical vapor deposition techniques known to those of ordinary skill in the art. Such processes include vapor deposition, cathode sputtering, pyrolysis, ion plating, e-beam deposition, and the like. Vapor deposition and cathode sputtering are often preferred in view of the uniformity of structure and thickness that can be obtained. Reference is made to Vacuum Deposition of Thin Substrates, L. Holland, 1970, Chapman and Hall, London, England with regard to the many available means of providing metal vapors and vapor coating techniques. If desired, the metal coating layer may be pattern coated by means of a mask, so that the metallic surface may be patterned.

The physical vapor deposition processes of the invention involve the deposition of atoms, typically by evaporation or sputtering in a vacuum. PVD processes can be characterized by the steps of (1) generating a metallic vapor by evaporation or sputtering using resistance, induction, electron-beam heating, laser-beam ablation, direct current plasma generation, radio-frequency plasma generation, molecular beam epitaxy, or similar means; (2) transport of the metallic vapor from the source to the substrate by molecular flow, viscous flow, plasma gas transport, or the like; and (3) particle growth on the polymer substrate, wherein nucleation and growth of the particles occurs. With PVD a variety of substrate temperatures can be used to control the crystallization and growth mode of the material deposited, although generally the temperature of the thermoplastic polymer substrate is below the distortion temperature of the polymer.

To avoid deformation or melting of the substrate during deposition, the substrate is generally maintained at a temperature at or below the distortion temperature of the polymer. The integrity of the polymer substrate is maintained by controlling the deposition rate so that the temperature of the particles, or the heat released by the particles upon deposition (heat of condensation) does not lead to thermal deformation of the polymer substrate. Generally, the temperature of the polymer substrate is maintained at ambient conditions of the deposition chamber, and no special cooling of the substrate is required.

In other embodiments, the particle coatings are applied to the polymer substrate by electron beam evaporation. This technique is based on heat production by high-energy electron beam bombardment on the metal to be deposited. The electron beam is generated by an electron gun, which uses the thermionic emission of electrons produced by an incandescent filament (cathode). Emitted electrons are accelerated towards an anode by a high difference of potential (kilovolts). The crucible (containing the source metal) itself or a near perforated disc can act as the anode. A magnetic field is often applied to bend the electron trajectory, allowing the electron gun to be positioned below the evaporation line. As electrons can be focused, it is possible to obtain a very localized heating on the metallic material to evaporate, with a high density of evaporation power (several kW). This allows control of the evaporation rate, from low to very high values. Cooling the crucible avoids contamination problems from heating and degasification.

Physical vapor deposition by sputtering is accomplished in a partial vacuum (between 13.3 to 1.33 Pa for a diode system and between 1.3 to 0.13 Pa for a magnetron system) when the target (usually a cathode) is bombarded with gas ions propelled by an electric field. The sputtering gas is typically a noble gas such as argon but the sputtering gas could include reactive elements that can be incorporated into the deposited substrate such as the deposition of nitrides, oxides and carbides. When the sputtering gas is ionized a glow discharge or plasma is produced. The gas ions are accelerated towards the target by an electric or electric and magnetic fields. Atoms from the target are ejected by momentum transfer and move across the vacuum chamber to be deposited on the substrate (the thermoplastic polymer substrate).

In another embodiment, the metal coatings are applied to the polymer substrate by sputter deposition. The sputtering apparatus generally consists of a three-source magnetron sputtering system arranged around the outer circumference of a cylindrical chamber containing a 38 cm (15 inch) diameter rotating drum. The substrates were mounted on the drum and rotated sequentially past positions in front of the sputtering sources at rates of between 1 and 8 rpm. The sources are shielded such that the sample is not coated from any two fluxes at the same time. The rate of material deposition and speed of rotation of the substrate in front of the targets determines the individual layer thicknesses comprising the final catalyst particles. Any vacuum pump that can draw a sufficient vacuum may be used. One such vacuum pump is a Varian AV8 cryopump (Varian Associates, Lexington, Mass.), which can be used in conjunction with an Alcatel 2012A rotary vane-roughing pump (Alcatel Vacuum Products, Hingham, Mass.). The cryopump may be partially isolated from the chamber by a butterfly valve, During deposition pressure may be maintained at 0.28 Pa (2.1 millitorr) as the sputtering gas flow rate was controlled by MKS flow controllers (MKS Instruments Inc., Andover, Mass.). Any inert or reactive sputtering gases may be used. Preferably either argon or an argon, oxygen mix is used. Control of the oxygen stoichiometry can be achieved by varying the argon/oxygen flow ratio. Any appropriate targets and power sources may be used. In one embodiment, an Advanced Energy MDX 500 power supply (Advanced Energy Industries, Inc., Fort Collins, Colo.) is used in the constant power mode of the power supply.

The process may involve evaporation of the elemental metal itself, as with Au or Ag, or may involve evaporation of a precursor form with generation of the actual elemental metal taking place during the transport stage prior to contacting the polymeric substrate. An example would be evaporation of silver metal using argon as a nonreactive gas with subsequent exposure of the silver particles to a reactive oxygen environment, thereby forming ultratine silver oxide coated particles (the particle core being silver) prior to contacting the polymeric substrate. Since the reactive gas is introduced at a site remote from the vaporization source after the particles have formed, the final particles consist of a central core and an outer shell, where the central core can be metal and where the outer shell can be comprised of a layer formed by reaction of the reactive gas with the metal particles.

When used, the inert gas is generally selected from He, Ne, Ar, Xe, and N₂. Mixtures of two or more nonreactive gases can also be used. When modification of the metal is desired, a reactive gas can be introduced through a gas inlet that is positioned so as to minimize reaction with the bulk material in the crucible and allow thorough mixing of the reactive gas with the particles entrained in the gas stream, thereby allowing reaction with the particles to occur. The reactive and nonreactive gases generally are at room temperature but the temperature can be elevated or reduced as desired. The term reactive includes 1) direct reaction with the particles, as in the case of metals, for example, with O₂, NO, NO₂, CO₂, CO, trimethylchlorosilane, methylamine, ethylene oxide, water, HF, HCl, or SO₂, or combinations thereof, to form the corresponding oxides or other compounds; or 2) adsorption, in which a volatile substance is introduced in the gas prior to contacting the dispersing medium, but the substance is either not a liquid under normal conditions (atmospheric pressure and 25° C.), the substance is not miscible with the dispersing medium, or else the substance acts to protect the surface of the particles from the dispersing medium or additives within the dispersing medium. Typical substances that could be adsorbed include polymers such as poly(methylmethacrylate) and polystyrene.

A useful apparatus for coating of the particles comprises: a) a furnace connected to a collection vessel, the furnace containing a heating means (e.g., resistive, inductive, e-beam, infrared, laser, plasma jet) and adapted to contain at least a first and optionally a second gas inlet tube, said second tube being located downstream from said first tube, and a means (e.g., a pump such as a rotary oil pump, an oil diffusion pump, piston pump, a Roots™ blower, and a turbomolecular pump) for evacuating the furnace and collection vessel, the vessel containing a dispersing medium; b) means (e.g., a ceramic, or metal crucible or slab that can be preloaded with metal or which can be continuously or batch-wise fed during operation of the apparatus, or the electrodes can be the means) for introducing a metal into said furnace and evacuation thereof; c) optionally, means (e.g., micro metering valve, electronic flow controller, or gas dispersing tube) for introducing through the first inlet tube a first, non-reactive gas stream into the furnace; d) means (e.g., energy input as by e-beam, infrared, laser, inductive, resistive, or plasma jet) for evaporating the metal particles into the first gas stream; e) means for allowing condensation of the vaporized metallic particles (e.g., decreasing the temperature, raising the pressure, changing the chemical nature of the nonreactive gas, controlling the length of the transfer tube, controlling the gas flow rate, or combinations thereof) in the first gas stream to produce a dispersion of particles into the first gas stream; f) optionally, means (e.g., a micro metering valve, electronic flow controller, or gas dispersing tube) for introducing into the furnace through the second inlet tube a second, reactive gas stream, to allow reaction with the metallic particles; g) means for impinging the particles onto the polymer substrate.

Other reactor designs to provide dispersions of the invention can be envisioned, including a rotary metal atom reactor such as described in Metal Vapour Synthesis in Organometallic Chemistry, J. R. Blackborow and D. Young, Springer-Verlag (New York), 1979 and a spinning disk assembly such as described in Jpn. J. Appl. Phys., 13, 749 (1974). Both types of reactors could be used to generate dispersions of organic pigments. In addition to resistive heating, other means of applying heat to the pigment or pigment precursor may be envisioned. These include laser heating, inductive heating, plasma jet, plasma arc discharge, and others known to those skilled in the art. With the process of the invention, no milling or chemical reduction processes are required in order to achieve the fine particle sizes obtained in the final coating.

### EXAMPLES

The examples are merely for illustrative purposes only and are not meant to be limiting on the scope of the appended claims.

### Example 1

One illustrative process encompasses a method to produce a decorative flexible metallic material by vapor depositing by Physical Vapor Deposition (PVD) a metal on one or both sides of polymer substrate, for example, a polyurethane foam substrate. Preferably, the metal is applied in a uniform layer. The layer can be applied in a non opaque thickness in a range from 200 to 999 angstroms, thereby allowing the underlying color or pattern to be seen through and highlighted by the metal layer. Additionally, the metal layer can be applied in an opaque thickness of at least 1000 angstroms to one or both sides of the substrate to completely obscure the underlying color or pattern.

### Example 2

Another illustrative process encompasses a method to enhance the qualities of a polyurethane foam bandage material by vapor depositing by PVD antimicrobial metals such as Copper and Silver or a combination of Copper and Silver, by co-deposition, concurrent deposition, or by use of a Copper/Silver alloy varying in composition from 1% to 99% to a total thickness of at least 500 angstroms

One illustrative product formed by the compositions of the invention is a thin—typically 1/32″-polyurethane foam bandage material commonly known as Pre-wrap, which is widely used as a soft intermediary layer used under cloth bandages and athletic equipment. The bandage type polyurethane foam is compatible with PVD processes and allows it to be coated with antimicrobial metals including, but not limited to, copper and silver, greatly enhancing its usefulness and capability.

### Example 3

Polyurethane foam is produced in a chemical reaction which is fully cured at the end of the production line. However, results of PVD processing has shown that a more brilliant coating occurs when the foam is allowed to age for several weeks. To this end we have discovered that elevated temperature or exposure to a strong oxidizing agent such as hydrogen peroxide can dramatically reduce the aging time.

The Material Safety Data Sheet from the foam manufacturer lists strong oxidizing agents as a compatibility issue due to accelerated degradation. Based on the information from the MSDS and testing, the apparent mechanism for acceleration of the aging of the material appears to be related.

Elevated temperature tests were run in an oven at 100° C. A time duration of 1 hour was effective for cut pieces of the PU foam material, while rolls require a longer soak time to compensate for the insulating properties of the foam, allowing the temperature to penetrate the inside of the roll. Roll time durations are dependent on the length of roll as well as tension of the roll which further increases the insulating properties. Hydrogen peroxide soak with a time duration of 1 hour was effective for cut pieces of foam.

In further studies, extended exposure to elevated temperatures in excess of 20 hours at 100 results in a transformation of the polyurethane foam. The material shrinks and the 3 dimensional cellular structure “lays down,” resulting in a flatter glossier structure that produces a unique effect with PVD coatings, retaining much of the sparkle aesthetic with a significantly enhanced gloss/sheen. The enhanced sheen improves the aesthetic in indoor lighting conditions particularly with fluorescent lighting which fails to produce the sparkle effect of the PVD coated material.

In the specification, there have been disclosed typical preferred embodiments of the invention and, although specific terms are employed, they are used in a generic and descriptive sense only and not for purposes of limitation. Obviously many modifications and variations of the invention are possible in light of the above teachings. It is therefore to be understood that the invention may be practiced otherwise than as specifically described.

Unless defined otherwise, all technical and scientific terms and any acronyms used herein have the same meanings as commonly understood by one of ordinary skill in the art in the field of this invention. Although any compositions, methods, kits, and means for communicating information similar or equivalent to those described herein can be used to practice this invention, the preferred compositions, methods, kits, and means for communicating information are described herein.

All references cited above are incorporated herein by reference to the extent allowed by law. The discussion of those references is intended merely to summarize the assertions made by their authors. No admission is made that any reference (or a portion of any reference) is relevant prior art. Applicants reserve the right to challenge the accuracy and pertinence of any cited reference.

What is claimed is:

1. A composition comprising polyurethane coated with one or more metals to form one or more thin-substrate metal layers.

2. The composition of claim 1, wherein the polyurethane is polyurethane foam.

3. The composition of claim 1, wherein the polyurethane is polyurethane fabric.

4. The composition of claim 1, wherein the metal comprises aluminum, copper, silver, gold, chromium, titanium, palladium, zinc, and platinum or a mixture thereof.

5. The composition of claim 1, wherein the polyurethane foam is in an open cell structure.

6. The composition of claim 1, wherein the polyurethane fabric is Lycra or Spandex.

7. The composition of claim 1, wherein the one or more thin substrate metal layers comprise uniform layers coating the polyurethane.

8. The composition of claim 1, wherein the one or more thin-substrate metal layers comprise a thickness of about 20 Angstroms to 2000 Angstroms.

9. The composition of claim 1, wherein the one or more thin-substrate metal layers comprise a thickness of about 100 Angstroms to 1500 Angstroms.

10. The composition of claim 1, wherein the one or more thin-substrate metal layers comprise a thickness of about 200 Angstroms to 1000 Angstroms.

11. The composition of claim 1, wherein the thin-substrate metal layers comprise more than one layer.

12. The composition of claim 1, wherein the polyurethane is coated with copper and silver.

13. The composition of claim 12, wherein the copper and silver vary in amount from about 1% to about 99%.

14. The composition of claim 12, wherein the copper and silver vary in amount from about 1% to about 99%, and have a total thickness of about 500 Angstroms.

15. A method of providing one or more metal layers to a polyurethane substrate comprising:
a. applying a thin substrate of a metal by physical vapor deposition onto the surface of the polyurethane substrate.

16. The method of claim 15, wherein the polyurethane substrate is polyurethane foam.

17. The method of claim 15, wherein the polyurethane substrate is polyurethane fabric.

18. The method of claim 15, wherein the metal comprises aluminum, copper, silver, gold, chromium, titanium, palladium, zinc, and platinum or a mixture thereof.

19. The method of claim 16, wherein the polyurethane foam is in an open cell structure.

20. The method of claim 17, wherein the polyurethane fabric is Lycra or Spandex.

21. The method of claim 15, wherein the one or more thin-substrate metal layers comprise uniform layers coating the polyurethane.

22. The method of claim 15, wherein the one or more thin-substrate metal layers comprise a thickness of about 20 Angstroms to 2000 Angstroms.

23. The method of claim 15, wherein the one or more thin-substrate metal layers comprise a thickness of about 100 Angstroms to 1500 Angstroms.

24. The method of claim 15, wherein the one or more thin-substrate metal layers comprise a thickness of about 200 Angstroms to 1000 Angstroms.

25. The method of claim 15, wherein applying one or more additional thin substrates of a metal by physical vapor deposition onto the surface of the polyurethane substrate.

26. The method of claim 25, wherein the polyurethane is coated with copper and silver.

27. The method of claim 26, wherein the copper and silver vary in amount from about 1% to about 99%.

28. The method of claim 27, wherein the copper and silver vary in amount from about 1% to about 99% and have a total thickness of about 500 Angstroms.
